(19) United States
(12) Patent Application Publication
(10) Pub. No.: US 2015/0168499 A1
(43) Pub. Date: Jun. 18, 2015

(54) BATTERY TESTER AND BATTERY REGISTRATION TOOL

(71) Applicant: Midtronics, Inc., Willowbrook, IL (US)

(72) Inventor: Andrew J. Palmisano, Darien, IL (US)

(21) Appl. No.: 14/565,589

(22) Filed: Dec. 10, 2014

Related U.S. Application Data
(60) Provisional application No. 61/915,157, filed on Dec. 12, 2013.

(51) Int. Cl. G01R 31/36

(52) U.S. Cl. CPC G01R 31/3648; G01R 31/3606

(57) ABSTRACT

A tool for programming electronic battery monitors includes a sensor configured to couple to a storage battery and sense an electrical parameter of the storage battery, I/O circuitry configured to couple to an electronic battery monitor and communicate with the electronic battery monitor, and a microprocessor configured to perform a battery test on the storage battery using the sensor. The microprocessor is further configured to store data in a memory in the electronic battery monitor through the I/O circuitry as a function of a result of the battery test.

### CROSS-REFERENCE TO RELATED APPLICATION

The present application is based on and claims the benefit of U.S. provisional patent application Ser. No. 61/915,157, filed Dec. 12, 2013, the content of which is hereby incorporated by reference in its entirety.

### BACKGROUND

The present invention relates to electronic battery monitors of the type used to couple to batteries used in automotive vehicles. More specifically, the present invention relates to programming such monitors.

Electronic battery monitors are typically configured to be permanently coupled to batteries of automotive vehicles. The monitors may be configured to measure various parameters including current, voltage and temperature.

Various types of techniques are known for monitoring batteries and related systems. Examples of electronic testers and related technologies are shown in: U.S. Pat. No. 3,873,911, issued Mar. 25, 1975, to Champlin; U.S. Pat. No. 3,909,708, issued Sep. 30, 1975, to Champlin; U.S. Pat. No. 4,816,768, issued Mar. 28, 1989, to Champlin; U.S. Pat. No. 4,825,170, issued Apr. 25, 1989, to Champlin; U.S. Pat. No. 4,881,038, issued Nov. 14, 1989, to Champlin; U.S. Pat. No. 4,912,416, issued Mar. 27, 1990, to Champlin; U.S. Pat. No. 5,140,269, issued Aug. 18, 1992, to Champlin; U.S. Pat. No. 5,343,380, issued Aug. 30, 1994; U.S. Pat. No. 5,572,136, issued Nov. 5, 1996; U.S. Pat. No. 5,574,355, issued Nov. 12, 1996; U.S. Pat. No. 5,583,416, issued Dec. 10, 1996; U.S. Pat. No. 5,585,728, issued Dec. 17, 1996; U.S. Pat. No. 5,589,757, issued Dec. 31, 1996; U.S. Pat. No. 5,592,093, issued Jan. 7, 1997; U.S. Pat. No. 5,598,098, issued Jan. 28, 1997; U.S. Pat. No. 5,656,920, issued Aug. 12, 1997; U.S. Pat. No. 5,757,192, issued May 26, 1998; U.S. Pat. No. 5,821,756, issued Oct. 13, 1998; U.S. Pat. No. 5,831,435, issued Nov. 3, 1998; U.S. Pat. No. 5,871,858, issued Feb. 16, 1999; U.S. Pat. No. 5,914,605, issued Jun. 22, 1999; U.S. Pat. No. 5,945,829, issued Aug. 31, 1999; U.S. Pat. No. 6,002,238, issued Dec. 14, 1999; U.S. Pat. No. 6,037,751, issued Mar. 14, 2000; U.S. Pat. No. 6,037,777, issued Mar. 14, 2000; U.S. Pat. No. 6,051,976, issued Apr. 18, 2000; U.S. Pat. No. 6,081,098, issued Jun. 27, 2000; U.S. Pat. No. 6,091,245, issued Jul. 18, 2000; U.S. Pat. No. 6,104,167, issued Aug. 15, 2000; U.S. Pat. No. 6,137,269, issued Oct. 24, 2000; U.S. Pat. No. 6,163,156, issued Dec. 19, 2000; U.S. Pat. No. 6,172,483, issued Jan. 9, 2001; U.S. Pat. No. 6,172,505, issued Jan. 9, 2001; U.S. Pat. No. 6,222,369, issued Apr. 24, 2001; U.S. Pat. No. 6,225,808, issued May 1, 2001; U.S. Pat. No. 6,249,124, issued Jun. 19, 2001; U.S. Pat. No. 6,259,254, issued Jul. 10, 2001; U.S. Pat. No. 6,262,563, issued Jul. 17, 2001; U.S. Pat. No. 6,294,896, issued Sep. 25, 2001; U.S. Pat. No. 6,294,897, issued Sep. 25, 2001; U.S. Pat. No. 6,304,087, issued Oct. 16, 2001; U.S. Pat. No. 6,310,481, issued Oct. 30, 2001; U.S. Pat. No. 6,313,607, issued Nov. 6, 2001; U.S. Pat. No. 6,313,608, issued Nov. 6, 2001; U.S. Pat. No. 6,316,914, issued Nov. 13, 2001; U.S. Pat. No. 6,323,650, issued Nov. 27, 2001; U.S. Pat. No. 6,329,793, issued Dec. 11, 2001; U.S. Pat. No. 6,331,762, issued Dec. 18, 2001; U.S. Pat. No. 6,332,113, issued Dec. 18, 2001; U.S. Pat. No. 6,351,102, issued Feb. 26, 2002; U.S. Pat. No. 6,359,441, issued Mar. 19, 2002; U.S. Pat. No. 6,363,303, issued Mar. 26, 2002; U.S. Pat. No. 6,377,031, issued Apr. 23, 2002; U.S. Pat. No. 6,392,414, issued May 21, 2002; U.S. Pat. No. 6,417,669, issued Jul. 9, 2002; U.S. Pat. No. 6,424,158, issued Jul. 23, 2002; U.S. Pat. No. 6,441,585, issued Aug. 17, 2002; U.S. Pat. No. 6,437,957, issued Aug. 20, 2002; U.S. Pat. No. 6,445,158, issued Sep. 3, 2002; U.S. Pat. No. 6,456,045; U.S. Pat. No. 6,466,025, issued Oct. 15, 2002; U.S. Pat. No. 6,465,908, issued Oct. 15, 2002; U.S. Pat. No. 6,466,026, issued Oct. 15, 2002; U.S. Pat. No. 6,469,511, issued Nov. 22, 2002; U.S. Pat. No. 6,495,990, issued Dec. 17, 2002; U.S. Pat. No. 6,497,209, issued Dec. 24, 2002; U.S. Pat. No. 6,507,196, issued Jan. 14, 2003; U.S. Pat. No. 6,534,993; issued Mar. 18, 2003; U.S. Pat. No. 6,544,078, issued Apr. 8, 2003; U.S. Pat. No. 6,556,019, issued Apr. 29, 2003; U.S. Pat. No. 6,566,883, issued May 20, 2003; U.S. Pat. No. 6,586,941, issued Jul. 1, 2003; U.S. Pat. No. 6,597,150, issued Jul. 22, 2003; U.S. Pat. No. 6,621,272, issued Sep. 16, 2003; U.S. Pat. No. 6,623,314, issued Sep. 23, 2003; U.S. Pat. No. 6,633,165, issued Oct. 14, 2003; U.S. Pat. No. 6,635,974, issued Oct. 21, 2003; U.S. Pat. No. 6,707,303, issued Mar. 16, 2004; U.S. Pat. No. 6,737,831, issued May 18, 2004; U.S. Pat. No. 6,744,149, issued Jun. 1, 2004; U.S. Pat. No. 6,759,849, issued Jul. 6, 2004; U.S. Pat. No. 6,781,382, issued Aug. 24, 2004; U.S. Pat. No. 6,788,025, filed Sep. 7, 2004; U.S. Pat. No. 6,795,782, issued Sep. 21, 2004; U.S. Pat. No. 6,805,090, filed Oct. 19, 2004; U.S. Pat. No. 6,806,716, filed Oct. 19, 2004; U.S. Pat. No. 6,850,037, filed Feb. 1, 2005; U.S. Pat. No. 6,850,037, issued Feb. 1, 2005; U.S. Pat. No. 6,871,151, issued march 22, 2005; U.S. Pat. No. 6,885,195, issued Apr. 26, 2005; U.S. Pat. No. 6,888,468, issued May 3, 2005; U.S. Pat. No. 6,891,378, issued May 10, 2005; U.S. Pat. No. 6,906,522, issued Jun. 14, 2005; U.S. Pat. No. 6,906,523, issued Jun. 14, 2005; U.S. Pat. No. 6,909,287, issued Jun. 21, 2005; U.S. Pat. No. 6,914,413, issued Jul. 5, 2005; U.S. Pat. No. 6,913,483, issued Jul. 5, 2005; U.S. Pat. No. 6,930,485, issued Aug. 16, 2005; U.S. Pat. No. 6,933,727, issued Aug. 23, 200; U.S. Pat. No. 6,941,234, filed Sep. 6, 2005; U.S. Pat. No. 6,967,484, issued Nov. 22, 2005; U.S. Pat. No. 6,998,847, issued Feb. 14, 2006; U.S. Pat. No. 7,003,410, issued Feb. 21, 2006; U.S. Pat. No. 7,003,411, issued Feb. 21, 2006; U.S. Pat. No. 7,012,433, issued Mar. 14, 2006; U.S. Pat. No. 7,015,674, issued Mar. 21, 2006; U.S. Pat. No. 7,034,541, issued Apr. 25, 2006; U.S. Pat. No. 7,039,533, issued May 2, 2006; U.S. Pat. No. 7,058,525, issued Jun. 6, 2006; U.S. Pat. No. 7,081,755, issued Jul. 25, 2006; U.S. Pat. No. 7,106,070, issued Sep. 12, 2006; U.S. Pat. No. 7,116,109, issued Oct. 3, 2006; U.S. Pat. No. 7,119,686, issued Oct. 10, 2006; and U.S. Pat. No. 7,126,341, issued Oct. 24, 2006; U.S. Pat. No. 7,154,276, issued Dec. 26, 2006; U.S. Pat. No. 7,198,510, issued Apr. 3, 2007; U.S. Pat. No. 7,363,175, issued Apr. 22, 2008; U.S. Pat. No. 7,208,914, issued Apr. 24, 2007; U.S. Pat. No. 7,246,015, issued Jul. 17, 2007; U.S. Pat. No. 7,295,936, issued Nov. 13, 2007; U.S. Pat. No. 7,319,304, issued Jan. 15, 2008; U.S. Pat. No. 7,363,175, issued Apr. 22, 2008; U.S. Pat. No. 7,398,176, issued Jul. 8, 2008; U.S. Pat. No. 7,408,358, issued Aug. 5, 2008; U.S. Pat. No. 7,425,833, issued Sep. 16, 2008; U.S. Pat. No. 7,446,536, issued Nov. 4, 2008; U.S. Pat. No. 7,479,763, issued Jan. 20, 2009; U.S. Pat. No. 7,498,767, issued Mar. 3, 2009; U.S. Pat. No. 7,501,795, issued Mar. 10, 2009; U.S. Pat. No. 7,505,856, issued Mar. 17, 2009; U.S. Pat. No. 7,545,146, issued Jun. 9, 2009; U.S. Pat. No. 7,557,586, issued Jul. 7, 2009; U.S. Pat. No. 7,595,643, issued Sep. 29, 2009; U.S. Pat. No. 7,598,699, issued Oct. 6, 2009; U.S. Pat. No. 7,598,744, issued Oct. 6, 2009; U.S. Pat. No. 7,598,743, issued Oct. 6, 2009; U.S. Pat. No. 7,619,417, issued Nov. 17, 2009; U.S. Pat. No. 7,642,786, issued Jan. 5, 2010; U.S. Pat. No. 7,642,787, issued Jan. 5, 2010; U.S. Pat. No. 7,656,162, issued Feb. 2, 2010; U.S. Pat. No. 7,688,074, issued Mar. 30, 2010; U.S. Pat. No. 7,705,602, issued Apr. 27, 2010; U.S. Pat. No. 7,706,992, issued Apr. 27, 2010; U.S. Pat. No. 7,710,119, issued May 4, 2010; U.S. Pat. No. 7,723,993, issued May 25, 2010; U.S. Pat. No. 7,728,597, issued Jun. 1, 2010; U.S. Pat. No. 7,772,850, issued Aug. 10, 2010; U.S. Pat. No. 7,774,151, issued Aug. 10, 2010; U.S. Pat. No. 7,777,612, issued Aug. 17, 2010; U.S. Pat. No. 7,791,348, issued Sep. 7, 2010; U.S. Pat. No. 7,808,375, issued Oct. 5, 2010; U.S. Pat. No. 7,924,015, issued Apr. 12, 2011; U.S. Pat. No. 7,940,053, issued May 10, 2011; U.S. Pat. No. 7,940,052, issued May 10, 2011; U.S. Pat. No. 7,959,476, issued Jun. 14, 2011; U.S. Pat. No. 7,977,914, issued Jul. 12, 2011; U.S. Pat. No. 7,999,505, issued Aug. 16, 2011; U.S. Pat. No. D643,759, issued Aug. 23, 2011; U.S. Pat. No. 8,164,343, issued Apr. 24, 2012; U.S. Pat. No. 8,198,900, issued Jun. 12, 2012; U.S. Pat. No. 8,203,345, issued Jun. 19, 2012; U.S. Pat. No. 8,237,448, issued Aug. 7, 2012; U.S. Pat. No. 8,306,690, issued Nov. 6, 2012; U.S. Pat. No. 8,344,685, issued Jan. 1, 2013; U.S. Pat. No. 8,436,619, issued May 7, 2013; U.S. Pat. No. 8,442,877, issued May 14, 2013; U.S. Pat. No. 8,493,022, issued Jul. 23, 2013; U.S. Pat. No. D687,727, issued Aug. 13, 2013; U.S. Pat. No. 8,513,949, issued Aug. 20, 2013; U.S. Pat. No. 8,674,654, issued Mar. 18, 2014; U.S. Pat. No. 8,674,711, issued Mar. 18, 2014; U.S. Pat. No. 8,704,483, issued Apr. 22, 2014; U.S. Pat. No. 8,738,309, issued May 27, 2014; U.S. Pat. No. 8,754,653, issued Jun. 17, 2014; U.S. Pat. No. 8,872,516, issued Oct. 28, 2014; U.S. Pat. No. 8,872,517, issued Oct. 28, 2014; U.S. Ser. No. 09/780,146, filed Feb. 9, 2001, entitled STORAGE BATTERY WITH INTEGRAL BATTERY TESTER; U.S. Ser. No. 09/756,638, filed Jan. 8, 2001, entitled METHOD AND APPARATUS FOR DETERMINING BATTERY PROPERTIES FROM COMPLEX IMPEDANCE/ADMITTANCE; U.S. Ser. No. 09/862,783, filed May 21, 2001, entitled METHOD AND APPARATUS FOR TESTING CELLS AND BATTERIES EMBEDDED IN SERIES/PARALLEL SYSTEMS; U.S. Ser. No. 09/880,473, filed Jun. 13, 2001; entitled BATTERY TEST MODULE; U.S. Ser. No. 10/042,451, filed Jan. 8, 2002, entitled BATTERY CHARGE CONTROL DEVICE; U.S. Ser. No. 10/109,734, filed Mar. 28, 2002, entitled APPARATUS AND METHOD FOR COUNTERACTING SELF DISCHARGE IN A STORAGE BATTERY; U.S. Ser. No. 10/112,998, filed Mar. 29, 2002, entitled BATTERY TESTER WITH BATTERY REPLACEMENT OUTPUT; U.S. Ser. No. 10/263,473, filed Oct. 2, 2002, entitled ELECTRONIC BATTERY TESTER WITH RELATIVE TEST OUTPUT; U.S. Ser. No. 10/310,385, filed Dec. 5, 2002, entitled BATTERY TEST MODULE; U.S. Ser. No. 09/653,963, filed Sep. 1, 2000, entitled SYSTEM AND METHOD FOR CONTROLLING POWER GENERATION AND STORAGE; U.S. Ser. No. 10/174,110, filed Jun. 18, 2002, entitled DAYTIME RUNNING LIGHT CONTROL USING AN INTELLIGENT POWER MANAGEMENT SYSTEM; U.S. Ser. No. 10/258,441, filed Apr. 9, 2003, entitled CURRENT MEASURING CIRCUIT SUITED FOR BATTERIES; U.S. Ser. No. 10/681,666, filed Oct. 8, 2003, entitled ELECTRONIC BATTERY TESTER WITH PROBE LIGHT; U.S. Ser. No. 10/867,385, filed Jun. 14, 2004, entitled ENERGY MANAGEMENT SYSTEM FOR AUTOMOTIVE VEHICLE; U.S. Ser. No. 10/958,812, filed Oct. 5, 2004, entitled SCAN TOOL FOR ELECTRONIC BATTERY TESTER; U.S. Ser. No. 60/587,232, filed Dec. 14, 2004, entitled CELLTRON ULTRA, U.S. Ser. No. 60/653,537, filed Feb. 16, 2005, entitled CUSTOMER MANAGED WARRANTY CODE; U.S. Ser. No. 60/665,070, filed Mar. 24, 2005, entitled OHMMETER PROTECTION CIRCUIT; U.S. Ser. No. 60,694,199, filed Jun. 27, 2005, entitled GEL BATTERY CONDUCTANCE COMPENSATION; U.S. Ser. No. 60/705,389, filed Aug. 4, 2005, entitled PORTABLE TOOL THEFT PREVENTION SYSTEM, U.S. Ser. No. 11/207,419, filed Aug. 19, 2005, entitled SYSTEM FOR AUTOMATICALLY GATHERING BATTERY INFORMATION FOR USE DURING BATTERY TESTER/CHARGING, U.S. Ser. No. 60/712,322, filed Aug. 29, 2005, entitled AUTOMOTIVE VEHICLE ELECTRICAL SYSTEM DIAGNOSTIC DEVICE, U.S. Ser. No. 60/713,168, filed Aug. 31, 2005, entitled LOAD TESTER SIMULATION WITH DISCHARGE COMPENSATION, U.S. Ser. No. 60/731,881, filed Oct. 31, 2005, entitled PLUG-IN FEATURES FOR BATTERY TESTERS; U.S. Ser. No. 60/731,887, filed Oct. 31, 2005, entitled AUTOMOTIVE VEHICLE ELECTRICAL SYSTEM DIAGNOSTIC DEVICE; U.S. Ser. No. 11/304,004, filed Dec. 14, 2005, entitled BATTERY TESTER THAT CALCULATES ITS OWN REFERENCE VALUES; U.S. Ser. No. 60/751,853, filed Dec. 20, 2005, entitled BATTERY MONITORING SYSTEM; U.S. Ser. No. 11/304,004, filed Dec. 14, 2005, entitled BATTERY TESTER WITH CALCULATES ITS OWN REFERENCE VALUES; U.S. Ser. No. 60/751,853, filed Dec. 20, 2005, entitled BATTERY MONITORING SYSTEM; U.S. Ser. No. 11/356,443, filed Feb. 16, 2006, entitled ELECTRONIC BATTERY TESTER WITH NETWORK COMMUNICATION; U.S. Ser. No. 11/519,481, filed Sep. 12, 2006, entitled BROAD-BAND LOW-CONDUCTANCE CABLES FOR MAKING KELVIN CONNECTIONS TO ELECTROCHEMICAL CELLS AND BATTERIES; U.S. Ser. No. 60/847,064, filed Sep. 25, 2006, entitled STATIONARY BATTERY MONITORING ALGORITHMS; U.S. Ser. No. 60/950,182, filed Jul. 17, 2007, entitled BATTERY TESTER FOR HYBRID VEHICLE; U.S. Ser. No. 60/973,879, filed Sep. 20, 2007, entitled ELECTRONIC BATTERY TESTER FOR TESTING STATIONARY BATTERIES; U.S. Ser. No. 60/992,798, filed Dec. 6, 2007,entitled STORAGE BATTERY AND BATTERY TESTER; U.S. Ser. No. 61/061,848, filed Jun. 16, 2008, entitled KELVIN CLAMP FOR ELECTRONICALLY COUPLING TO A BATTERY CONTACT; U.S. Ser. No. 12/697,485, filed Feb. 1, 2010, entitled ELECTRONIC BATTERY TESTER; U.S. Ser. No. 12/712,456, filed Feb. 25, 2010, entitled METHOD AND APPARATU FOR DETECTING CELL DETERIORATION IN AN ELECTROCHEMICAL CELL OR BATTERY; U.S. Ser. No. 61/311,485, filed Mar. 8, 2010, entitled BATTERY TESTER WITH DATABUS FOR COMMUNICATING WITH VEHICLE ELECTRICAL SYSTEM; U.S. Ser. No. 61/313,893, filed Mar. 15, 2010, entitled USE OF BATTERY MANUFACTURE/SELL DATE IN DIAGNOSIS AND RECOVERY OF DISCHARGED BATTERIES; U.S. Ser. No. 12/758,407, filed Apr. 12, 2010, entitled ELECTRONIC BATTERY TESTER WITH NETWORK COMMUNICATION; U.S. Ser. No. 12/769,911, filed Apr. 29, 2010, entitled STATIONARY BATTERY TESTER; U.S. Ser. No. 61/330,497, filed May 3, 2010, entitled MAGIC WAND WITH ADVANCED HARNESS DETECTION; U.S. Ser. No. 61/348,901, filed May 27, 2010, entitled ELECTRTONIC BATTERY TESTER; U.S. Ser. No. 61/351,017, filed Jun. 3, 2010, entitled IMPROVED ELECTRIC VEHICLE AND HYBRID ELECTRIC VEHICLE BATTERY MODULE BALANCER; U.S. Ser. No. 12/818,290, filed Jun. 18, 2010, entitled BATTERY MAINTENANCE DEVICE WITH THERMAL BUFFER; U.S. Ser. No. 61/373,045, filed Aug. 12, 2010, entitled ELECTRONIC BATTERY TESTER FOR TESTING STATIONERY STORAGE BATTERY; U.S. Ser. No. 12/888,689, filed Sep. 23, 2010, entitled BATTERY TESTER FOR ELECTRIC VEHICLE; U.S. Ser. No. 61/411,162, filed Nov. 8, 2010, entitled ELECTRONIC BATTERY TESTER; U.S. Ser. No. 13/037,641, filed Mar. 1, 2011, entitled MONITOR FOR FRONT TERMINAL BATTERIES; U.S. Ser. No. 13/037,641, filed Mar. 1, 2011, entitled: MONITOR FOR FRONT TERMINAL BATTERIES; U.S. Ser. No. 13/098,661, filed May 2, 2011, entitled METHOD AND APPARATUS FOR MEASURING A PARAMETER OF A VEHICLE ELECTRICAL SYSTEM; U.S. Ser. No. 13/113,272, filed May 23, 2011, entitled ELECTORNIC STORAGE BATTERY DIAGNOSTIC SYSTEM; U.S. Ser. No. 13/152,711, filed Jun. 3, 2011, entitled BATTERY PACK MAINTENANCE FOR ELECTRIC VEHICLE; U.S. Ser. No. 13/205,949, filed Aug. 9, 2011, entitled ELECTRONIC BATTE4RY TESTER FOR TESTING STORAGE BATTERY; U.S. Ser. No. 13/270,828, filed Oct. 11, 2011, entitled SYSTEM FOR AUTOMATICALLY GATHERING BATTERY INFORMATION; U.S. Ser. No. 13/276,639, filed Oct. 19, 2011, entitled METHOD AND APPARATUS FOR MEASURING A PARAMETER OF A VEHICLE ELECTRICAL SYSTEM; U.S. Ser. No. 61/558,088, filed Nov. 10, 2011, entitled BATTERY PACK TESTER; U.S. Ser. No. 13/357,306, filed Jan. 24, 2012, entitled STORAGE BATTERY AND BATTERY TESTER; U.S. Ser. No. 61/665,555, filed Jun. 28, 2012, entitled HYBRID AND ELECTRIC VEHICLE BATTERY MAINTENANCE DEVICE; and U.S. Ser. No. 13/567,463, filed Aug. 6, 2012, entitled BATTERY TESTERS WITH SECONDARY FUNCATIONALITY; U.S. Ser. No. 13/668,523, filed Nov. 5, 2012, entitled BATTERY TESTER FOR ELECTRIC VEHICLE; U.S. Ser. No. 13/672,186, filed Nov. 8, 2012, entitled BATTERY PACK TESTER; U.S. Ser. No. 61/777,360, filed Mar. 12, 2013, entitled DETERMINATION OF STARTING CURRENT IN AN AUTOMOTIVE VEHICLE; U.S. Ser. No. 61/777,392, filed Mar. 12, 2013, entitled DETERMINATION OF CABLE DROP DURING A STARTING EVENT IN AN AUTOMOTIVE VEHICLE; U.S. Ser. No. 13/827,128, filed Mar. 14, 2013, entitled HYBRID AND ELECTRIC VEHICLE BATTERY MAINTENANCE DEVICE; U.S. Ser. No. 61/789,189, filed Mar. 15, 2013, entitled CURRENT CLAMP WITH JAW CLOSURE DETECTION; U.S. Ser. No. 61/824,056, filed May 16, 2013, entitled BATTERY TESTING SYSTEM AND METHOD; U.S. Ser. No. 61/859,991, filed Jul. 30, 2013, entitled METHOD AND APPARATUS FOR MONITRING A PLURALITY OF STORAGE BATTERIES IN A STATIONARY BACK-UP POWER SYSTEM; U.S. Ser. No. 14/039,746, filed Sep. 27, 2013, entitled BATTERY PACK MAINTENANCE FOR ELECTRIC VEHICLE; U.S. Ser. No. 61/915,157, filed Dec. 12, 2013, entitled BATTERY TESTER AND BATTERY REGISTRATION TOOL; U.S. Ser. No. 61/928,167, filed Jan. 16, 2014, entitled BATTERY CLAMP WITH ENDOSKELETON DESIGN; U.S. Ser. No. 14/204,286, filed Mar. 11, 2014, entitled CURRENT CLAMP WITH JAW CLOSURE DETECTION; U.S. Ser. No. 14/276,276, filed May 13, 2014, entitled BATTERY TESTING SYSTEM AND METHOD; U.S. Ser. No. 62/024,037, filed Jul. 14, 2014, entitled COMBINATION SERVICE TOOL; U.S. Ser. No. 62/055,884, filed Sep. 26, 2014, entitled CABLE CONNECTOR FOR ELECTORNIC BATTERY TESTR; all of which are incorporated herein by reference in their entireties.

### SUMMARY

A tool for programming electronic battery monitors includes a sensor configured to couple to a storage battery and sense an electrical parameter of the storage battery, I/O circuitry configured to couple to an electronic battery monitor and communicate with the electronic battery monitor, and a microprocessor configured to perform a battery test on the storage battery using the sensor. The microprocessor is further configured to store data in a memory in the electronic battery monitor through the I/O circuitry as a function of a result of the battery test.

### BRIEF DESCRIPTION OF THE DRAWINGS

FIG. 1 is a simplified diagram of an automotive vehicle including an electronic battery monitor coupled to the battery of the vehicle.

FIG. 2 is a simplified schematic diagram of the battery monitor of FIG. 1.

FIG. 3 is a simplified block diagram showing battery test circuitry.

### DETAILED DESCRIPTION OF ILLUSTRATIVE EMBODIMENTS

The present invention relates to battery testers and battery monitors. More specifically, the present invention relates to battery registration tools of the type used to store information in sensors and management systems of batteries used in automotive vehicles.

It is becoming commonplace for new cars to have battery sensors (monitors). These sensors measure voltage, current, and temperature. Furthermore, using these measurements, the sensors estimate the battery state of charge, state of health, and various other parameters. However, in order to do so, they require basic battery parameters to be programmed into the sensors. These parameters may include, but are not limited to the following:
Rated Amp Hours of Capacity
Rated CCA
Peukert Number
Battery chemistry, such as AGM or flooded

These sensors are typically programmed independently or through the vehicle. This is commonly known as “battery registration”. However, in some instances, there may not be a verification performed to ensure that the parameters programmed into the sensor actually match the battery mounted in the car. If the battery parameters listed above do not match the battery that is physically mounted in the car, then state of charge, state of health, and other calculations will be prone to error. Furthermore, if these parameters are not updated when a battery is changed, there is also an opportunity for error, especially if the replacement battery does not have the same characteristics as the original battery.

An additional consideration is that often times the rudimentary state of charge and state of health algorithms included in the battery sensors may become less accurate as batteries age. This is another source for error.

A third consideration is that battery registration is commonly done through the OBDII databus of the vehicle. Due to variations in the way each manufacturer programs its vehicles, and even variations within the same manufacturer for different vehicle models and model years, the battery registration process is different from vehicle to vehicle. This complicates the process across a wide variety of vehicles.

In one aspect, the present invention provides a new type of service tool or an enhancement to existing service tools. A battery tester is provided that can also program battery sensors (monitors), thereby reducing the opportunity for errors in the battery registration process. In one specific example, an operator enters the battery parameters into a battery maintenance tool. Next a battery test is performed to ensure that the battery meets manufacturer's recommendations. Upon receiving a positive test result, the operator may then program the applicable parameters into the battery sensor. This ensures that the battery sensor is properly programmed. Because the sensor is programmed directly, without the need to go through the OBDII databus of the vehicle, vehicle specific protocols are not necessary. Furthermore, this also allows the opportunity to use more accurate battery tester algorithms and techniques than a simple voltage-based algorithm which is commonly used in standard battery sensors. An improved algorithm may also be programmed into the vehicle at the same time that battery registration process is performed.

Battery sensors are referred to by a number of different names including battery control module, battery management system, battery management sensor, battery monitor sensor, intelligent battery sensor, BECB, battery monitor unit, electronic battery sensor, battery control unit, among others. Herein, referred to in general as electronic battery monitors. Example electronic battery monitors include ING-100, INGEN Battery Management System available from Midtronics Inc., the Intelligent Battery Sensor IBS 200x, the Delphi IVT battery sensor, as well as components such as the ADU C7039 available from Analog Devices, the AMS AG AS8510, among others. Communication with such devices includes various techniques including a Local Interconnect Network (LIN), a Controller Area Network (CAN), wireless technologies including Bluetooth® and WiFi, as well as OBDII. The sensors can be configured to calculate parameters of the battery including state of charge, state of health, or others.

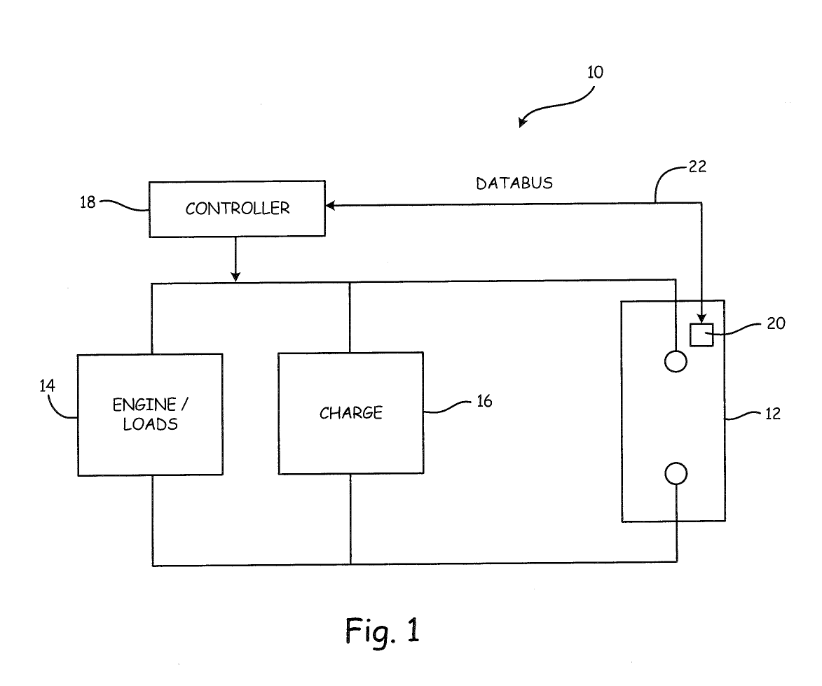

FIG. 1 is a simplified diagram of an automotive vehicle 10 including a storage battery 12, an engine/loads 14 and a charge system 16. Operation of the vehicle including the charge system and the loads are under the control of a controller 18. Vehicle 10 may be a conventional automotive vehicle, a hybrid or an electrical vehicle. During operation, power is drawn from battery 12 to power components of the vehicle. These may be traditional loads such as headlights, electric radios, engine components, etc. In case of a hybrid or electrical vehicle, engine 14 comprises one or more electric motors which are used to propel the vehicle. Some type of a charge system 16 is also provided. In a conventional vehicle, charge system 16 may be an alternator coupled to an internal combustion engine. A similar configuration can be used in a hybrid vehicle. Other charging techniques include those which use regenerative techniques such as regenerative braking in which the braking force is captured and used to charge the battery 12. Storage battery 12 may be a conventional 12 volt storage battery such as those typically used in automotive vehicles or may be a larger battery pack such as those used in hybrid or electrical vehicles. A battery sense monitor 20 is shown coupled to the battery 12. Operation of monitor 20 will be explained in more detail below. Monitor 20 collects information related to voltage, current and/or temperature of battery 12. This information is used in either raw form and provided to controller 18 over a databus 22, or used to perform diagnostic. Such diagnostics include determination of a state of health or state of charge of the battery 12.

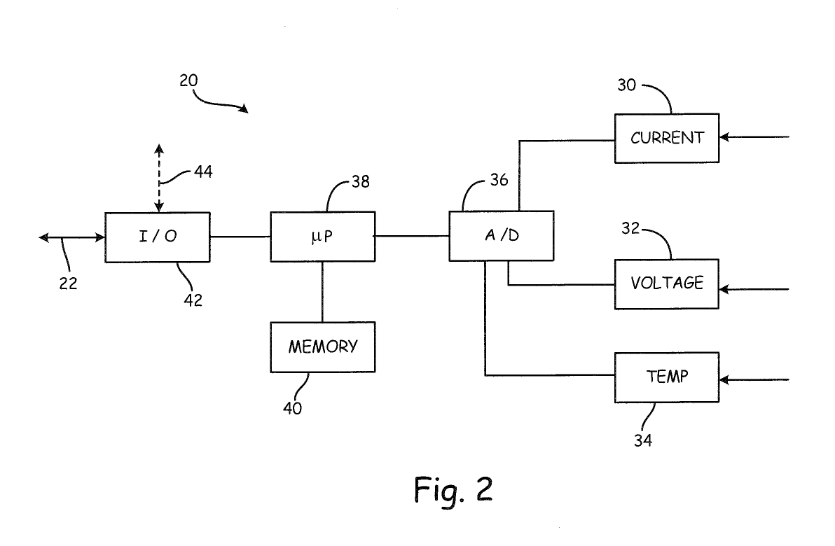

FIG. 2 is a simplified block diagram of electronic battery monitor 20. Monitor 20 includes various sensors such as current sensor 30, voltage sensor 32 and temperature sensor 34. Current sensor 30 can be coupled to the battery 12 such that it may sense the current flowing into and out of the battery 12. Similarly, voltage sensor 32 can be coupled to the terminals battery 12 to measure a voltage across the terminals. Temperature sensor 34 can be used to measure a temperature of the battery itself or other proximate components. Sensors 30, 32 and 34 coupled to an analog to digital converter 36 which digitizes their output and provides a representative digital signal to microprocessor 38. Microprocessor 38 operates in accordance with instructions and other values stored in memory 40 and is configured to communication using I/O circuitry 42.

During operation, microprocessor 38 monitors data collected from sensors 30, 32 and 34 and responsively communicates over databus 22. The data communicator over databus 22 may be raw values of monitored current, voltage or temperature, or may include other information. For example, microprocessor 38 may be configured to diagnose a condition of the battery based upon data collected from sensors 30, 32 and 34 and responsively communicate on databus 22. Such determinations includes battery state of health (SoH), battery state of charge (SocC) or other information. Such determinations are made using algorithms stored in the form of programming instructions in memory 40. The algorithms may include constant values including calibration values stored in memory 40. The communication over databus 22 may be made in accordance with any desired protocol including the CAN protocol, the LIN protocol, serial communication, as well as wireless protocols. A second optional databus 44 is also illustrated. Monitor 20 may include its own power source, however, typically monitor 20 will obtain power directly from the battery 12.

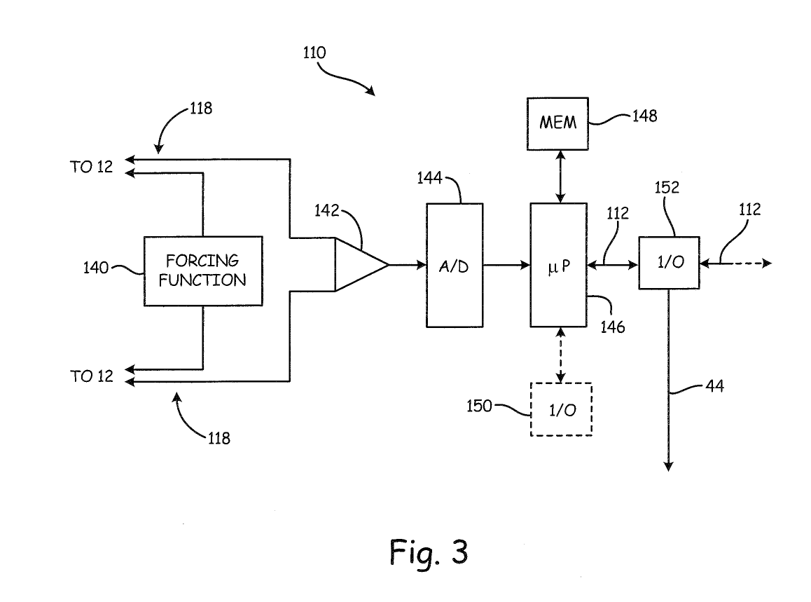

FIG. 3 is a block diagram of a battery test circuitry 110 or “tool” which includes a forcing function 140 and an amplifier 142 coupled to connectors 118. In the illustration of FIG. 3, connectors 118 are shown as Kelvin connections. In such a configuration, current is typically carried through one pair of terminals and a resultant voltage may be sensed with a second pair of terminals. The forcing function 140 can be any type of signal which has a time varying component including a transient signal. The forcing function can be through application of a load or by applying an active signal to battery 116. In one configuration, the forcing function 140 may be a component within the vehicle 10 itself For example, loads within the vehicle 10 may be applied to cause current to be drawn from the battery 12. Similarly, charge circuitry 16 shown in FIG. 1 may be used to apply a forcing function in battery 12. A response signal is sensed by amplifier 142 and provided to analog to digital converter 144 which couples to microprocessor 146. Microprocessor 146 operates in accordance with instructions stored in memory 148. Microprocessor 146 can store data into memory 148.

Input/output (I/O) 152 is provided for coupling to the databus 112. I/O 152 can be in accordance with the desired standard or protocol. Data collected by battery test circuitry 110 can be stored in memory 148 and transmitted over bus 112 when pulled by external circuitry 114. In one embodiment, input/output 152 comprises an RF (Radio Frequency) or IR (Infrared) input/output circuit and bus 112 comprises electromagnetic radiation. In one configuration, input/output circuitry 152 is used to provide a local operator interface, for example, a display and user input, whereby an operator may locally control the battery tester 110.

Of course, the illustration of FIG. 3 is simply one simplified embodiment and other embodiments are in accordance with the invention. Databus 112 may be capable of coupling directly to memory 148 for retrieval of stored data. Additionally, in the illustrated embodiment microprocessor 146 is configured to measure a dynamic parameter based upon the forcing function 140. This dynamic parameter can be correlated with battery condition as set forth in the above-mentioned Champlin and Midtronics, Inc. patents. As used herein, a dynamic parameter refers to a parameter of the battery 12 which is measured based upon a forcing function which has a time varying value. These include time varying values which change periodically, those of which are transient in nature, or some other combination thereof In one configuration, the forcing function is a relatively small signal in comparison with other loads drawn by the vehicle or applied to the battery. The forcing function may be a voltage or current signal, or some combination thereof Both real and imaginary representations of sensed data may be used in determining the dynamic parameter. However, other types of battery tests circuitry can be used in the present invention and certain aspects of the invention should not be limited to the specific embodiment illustrated herein.

FIG. 3 also illustrates an optional input/output block 150 which can be any other type of input and/or output coupled to microprocessor 146. For example, this can be used to couple to external devices or to facilitate user input and/or output. Databus 112 can also be used to provide data or instructions to microprocessor 146. This can instruct the microprocessor 146 to perform a certain test, transmit specified data, update programming instructions, constant test parameters, etc. stored in memory 148. Although a microprocessor 146 is shown, other types of computational or other circuitry can be used to collect and place data into memory 148.

Input/output circuitry 152 is also configured to communicate with, for example, databus 44 (or 22) coupled to circuitry 20 shown in FIG. 2 through I/O circuitry 42. Using this communication link, tool 112 can be used to place programming information, or other values, into memory 40 of the monitor 20. This may be used as described above to store values within the memory 40 including, for example, updating diagnostic algorithms or programming instructions stored in memory 40. Similarly, databus 44 (or 22) can be used to retrieve information from memory 40, or other information provided by microprocessor 38. This allows the retrieval of log information, programming instructions, constants, or other data from memory 40 by tool 110.

During operation, an operator couples the tool 110 to the automotive vehicle. For example, connectors 18 may be coupled to vehicle battery 12 and the I/O circuitry 152 may be coupled to a databus of the vehicle. An operator uses the tool 110 to perform a battery test on the battery using any appropriate technique such as those described herein. Based upon the battery test, it can be determined if the battery is an appropriate battery for the particular vehicle. Information related to the battery may be stored in the memory 40 of the electronic monitor 20 shown in FIG. 2. This information may be calibration information, ratings of the battery, date or time information, specific information related to battery type or condition as well as information related to the manufacturer of the battery. Other types of information may also be communicated to electronic monitor 20 and stored in memory 40. The information can be communicated based upon a manual input provided by the operator or may be sent automatically. Other information may also be communicated to monitor 20 including revisions to diagnostic procedures or testing algorithms or other updates related to programming, Constants, calibration values, or other information as desired. In one configuration, tool 110 includes a temperature sensor (for example, I/O module 150 may include a temperature sensor) whereby temperature calibration information may be provided to electronic monitor 20. Similarly, data may also be read from the memory 40 including stored information, programming instructions, etc. This may be, for example, information related to testing, diagnsotic information, information related to the life or usage of a battery or other information.

Although the present invention has been described with reference to preferred embodiments, workers skilled in the art will recognize that changes may be made in form and detail without departing from the spirit and scope of the invention. As used herein, the term “microprocessor” includes any digital controller or the like. Although a dynamic parameter is described with respect to FIG. 3, any parameter of the battery may be measured for use in performing the battery test.

What is claimed is:

1. A tool for programming electronic battery monitors, comprising:
a sensor configured to couple to a storage battery and sense an electrical parameter of the storage battery;
I/O circuitry configured to couple to an electronic battery monitor and communicate with the electronic battery monitor; and
a microprocessor configured to perform a battery test on the storage battery using the sensor and further configured to store data in a memory in the electronic battery monitor through the I/O circuitry as a function of a result of the battery test.

2. The apparatus of claim 1, wherein the microprocessor performs a test based upon a dynamic parameter.

3. The apparatus of claim 1, wherein the microprocessor measures a conductance of the battery.

4. The apparatus of claim 1, wherein the programming is related to amp hour capacity of the battery.

5. The apparatus of claim 1, wherein the stored data is related to CCA of the battery.

6. The apparatus of claim 1, wherein the stored data is related to the Peukert number of the battery.

7. The apparatus of claim 1, wherein the stored data is related to the battery chemistry.

8. The apparatus of claim 1, wherein the I/O directly communicates with a databus of the vehicle.

9. The apparatus of claim 8, wherein the databus is in accordance with the OBDII standard.

10. The apparatus of claim 1, wherein the stored data is related to a full charge open circuit voltage of the storage battery.

11. The apparatus of claim 1, wherein the stored data is related to a full discharge open circuit voltage of the storage battery.

12. The apparatus of claim 1, wherein the I/O circuitry is configured to communicate with a databus of the electronic battery monitor.

13. The apparatus of claim 12, wherein the databus is in accordance with the CAN standard.

14. The apparatus of claim 12, wherein the databus is in accordance with the LN standard.

15. The apparatus of claim 1, wherein the stored data is a function of the battery test of the storage battery.

16. The apparatus of claim 1, including a forcing function source configured to couple to the storage battery and apply a forcing function to the storage battery.

17. The apparatus of claim 16, wherein the sensor is configured to sense a response of the storage battery to the applied forcing function.

18. The apparatus of claim 1, including a local operator interface.

19. The apparatus of claim 1, wherein the stored data comprises calibration information.

20. The apparatus of claim 1, wherein the stored data comprises programming instructions related to an algorithm used by the electronic battery monitor to test the storage battery.

21. The apparatus of claim 1 wherein the I/O circuitry comprises wireless communication circuitry.

22. The apparatus of claim 1 wherein the I/O circuitry comprises wired communication circuitry.
